(19) United States
(12) Patent Application Publication
(10) Pub. No.: US 2024/0297010 A1
(43) Pub. Date: Sep. 5, 2024

(54) CONTROL METHOD OF WRITING APPARATUS AND WRITING APPARATUS

(71) Applicant: NuFlare Technology, Inc., Yokohama-shi (JP)

(72) Inventors: Eita FUJISAKI, Yokohama (JP); Takahito NAKAYAMA, Chigasaki (JP); Satoshi NAKAHASHI, Yokohama (JP)

(73) Assignee: NuFlare Technology, Inc., Yokohama-shi (JP)

(21) Appl. No.: 18/659,093

(22) Filed: May 9, 2024

Related U.S. Application Data
(63) Continuation of application No. PCT/JP2022/039796, filed on Oct. 25, 2022.

(30) Foreign Application Priority Data
Nov. 18, 2021 (JP) 2021-188110

(51) Int. Cl. H01J 37/04; H01J 37/20; H01J 37/317

(52) U.S. Cl. CPC H01J 37/045; H01J 37/20; H01J 37/3177; H01J 2237/0435; H01J 2237/202

(57) ABSTRACT

A writing apparatus irradiates a predetermined position on an irradiation target with multiple charged particle beams to write a predetermined pattern on the irradiation target. The writing apparatus includes a beam generation mechanism generating multiple charged particle beams; a blanking aperture mechanism comprising a limiting aperture substrate shielding the generated multiple charged particle beams and a deflector deflecting the multiple charged particle beams in a predetermined direction, and blanking the multiple charged particle beams; a stage having the irradiation target mounted thereon and being movable; a driver moving the limiting aperture substrate; and a controller controlling the writing apparatus. The controller moves the limiting aperture substrate from an arrangement location at the time of writing in a plane perpendicular to an axial direction of the multiple charged particle beams in a blanking period, and returns the limiting aperture substrate to the arrangement location at the time of writing.

### CROSS REFERENCE TO RELATED APPLICATIONS

This application is based upon and claims the benefit of priority from the prior International Patent Application No. PCT/JP/2022/039796, filed on Oct. 25, 2022 and the prior Japanese Patent Application No. 2021-188110, filed on Nov. 18, 2021, the entire contents of which are incorporated herein by reference.

### FIELD

The embodiments of the present invention relate to a control method of a writing apparatus and a writing apparatus.

### BACKGROUND

A writing apparatus irradiates a mask blank with a charged particle beam emitted from an electron gun to expose a sensitive material on the mask blank in a desired pattern. In the writing apparatus, the charged particle beam is passed through an aperture array to generate desired multiple beams (multi-beams).

Narrowing an interelectrode gap of a blanker and greatly deflecting the multi-beams to cause scattered beams to be negligibly small is conceivable. However, if the gap between the electrodes of the blanker is extremely small, problems such as irradiation of the electrodes with the multi-beams occur.

At the time of generation of the multi-beams, the sidewall and the like of the aperture are also irradiated with the charged particle beam and a large quantity of scattered electrons are generated from the aperture sidewall, whereby leaked beams are generated. A blanking aperture mechanism is provided on the downstream side of a shaping aperture array to control irradiation with the multi-beams individually or collectively. However, the leaked beams cannot be controlled by this mechanism and there is a risk that the mask blank is irradiated with the leaked beams. In this case, the sensitive material on the mask blank is at a risk of being unintentionally exposed to the leaked beams.

### BRIEF DESCRIPTION OF THE DRAWINGS

FIG. 1 is a diagram illustrating a configuration example of a writing apparatus according to a first embodiment;

FIG. 2A is a conceptual diagram illustrating a state of the writing apparatus in beam ON;

FIG. 2B is a conceptual diagram illustrating a state of the writing apparatus 100 in beam OFF;

FIG. 3 is a flowchart illustrating a control method of the writing apparatus in soaking processing;

FIG. 4 is a flowchart illustrating a control method of the writing apparatus in Z-map measurement processing;

FIG. 5 is a flowchart illustrating a control method of the writing apparatus in writing processing; and

FIG. 6 is a conceptual diagram illustrating scanning with multi-beams in the writing processing.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A writing apparatus according to the present embodiment irradiates a predetermined position on an irradiation target with multiple charged particle beams to write a predetermined pattern on the irradiation target, the apparatus comprising: a beam generation mechanism configured to generate multiple charged particle beams; a blanking aperture mechanism comprising a limiting aperture substrate configured to shield the generated multiple charged particle beams and a deflector configured to deflect the multiple charged particle beams in a predetermined direction, and configured to blank the multiple charged particle beams; a stage configured to have the irradiation target mounted thereon and to be movable; a driver configured to move the limiting aperture substrate; and a controller configured to control the writing apparatus, wherein the controller moves the limiting aperture substrate from an arrangement location at a time of the writing in a plane perpendicular to an axial direction of the multiple charged particle beams in a period of the blanking, and returns the limiting aperture substrate to the arrangement location at a time of the writing.

A writing method according to the present embodiment is a method of irradiating a predetermined position on an irradiation target with multiple charged particle beams to write a predetermined pattern on the irradiation target, the method comprising: generating multiple charged particle beams; deflecting the generated multiple charged particle beams in a predetermined direction to blank the multiple charged particle beams with a limiting aperture substrate; and moving the limiting aperture substrate from an arrangement location at a time of the writing in a plane perpendicular to an axial direction of the multiple charged particle beams in a period of the blanking, and returning the limiting aperture substrate to the arrangement location at a time of the writing.

### First Embodiment

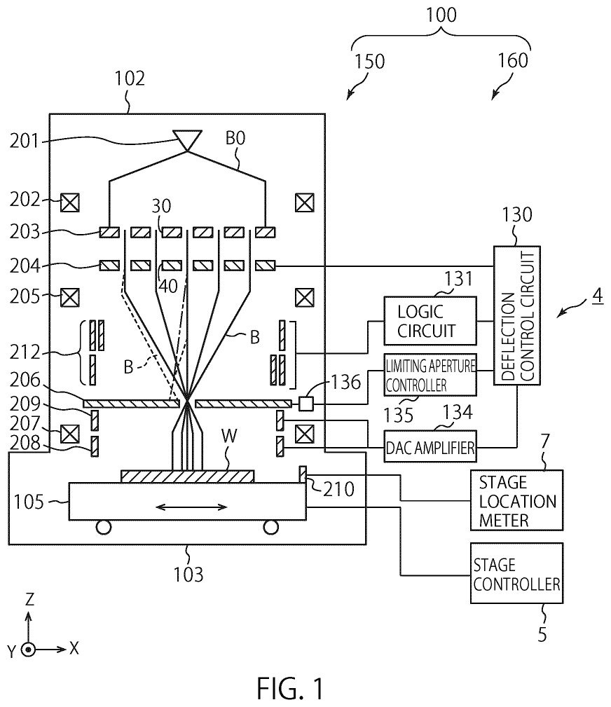

FIG. 1 is a diagram illustrating a configuration example of a writing apparatus according to a first embodiment. A writing apparatus 100 is, for example, a charged particle beam exposure apparatus of a multi-beam system and is used to write a photomask or a template for lithography used in manufacturing of semiconductor devices. The present embodiment may be applied to an apparatus that irradiates a specimen W with an electron beam or an ion beam, such as an exposure apparatus and an electron microscope as well as a writing apparatus. Therefore, the specimen W as a processing target may be a semiconductor substrate or the like, as well as the mask blank.

The writing apparatus 100 includes a writing part 150 and a controller 160. The writing part 150 includes an electron lens barrel 102 and a writing chamber 103. The controller 160 includes an irradiation controller 4, a stage controller 5, a stage location meter 7, a logic circuit 131, a DAC (Digital-to-Analog Converter) amplifier 134, and a limiting aperture controller 135.

An electron gun 201, an illuminating lens 202, a shaping aperture array substrate 203, a blanking aperture array substrate 204, a reducing lens 205, a limiting aperture substrate 206, an objective lens 207, a main deflector 208, a sub deflector 209, a blanking deflector 212, and a limiting aperture driver 136 are placed in the electron lens barrel 102.

A stage 105 that can be moved in an X direction and a Y direction orthogonal to each other (a substantially horizontal direction) is placed in the writing chamber 103. A specimen W, such as a mask blank, being an irradiation target of multi-beams at the time of writing can be mounted on the stage 105. The specimen W is, for example, a mask blank including a light-shielding film such as a chrome film and a resist film stacked on a glass substrate. A mirror 210 is arranged on the stage 105 to measure the location of the stage 105. The inner portions of the electron lens barrel 102 and the writing chamber 103 are evacuated to be brought to a depressurized state.

The electron gun 201 functioning as a beam irradiating part generates a charged particle beam B0. The charged particle beam B0 is, for example, an electron beam or an ion beam. The specimen W is irradiated with the charged particle beam B0 generated by the electron gun 201.

The shaping aperture array substrate 203 has a plurality of openings 30, for example, arrayed in m columns and n rows (m, n≥2) at a predetermined arrangement pitch. The openings 30 are formed in rectangles having the same dimension and the same shape. The shape of the openings 30 may be a circle. The charged particle beam B0 emitted from the electron gun 201 is caused by the illuminating lens 202 to substantially perpendicularly illuminate the entire shaping aperture array substrate 203. The charged particle beam B0 illuminates a region including all the openings 30 of the shaping aperture array substrate 203. A part of the charged particle beam B0 passes the openings 30 to be shaped into multi-beams B. In this way, the shaping aperture array substrate 203 generates the multi-beams B by shaping the charged particle beam B0 from the electron gun 201.

The blanking aperture array substrate 204 includes a plurality of openings 40 corresponding to arrangement locations of the openings 30 of the shaping aperture array substrate 203. Although not illustrated, a pair of two electrodes (blankers) are arranged for each of the openings 40. The multi-beams B passing through the openings 40 are independently deflected by a voltage applied to each pair of the two electrodes. That is, the blankers perform blanking deflection of the corresponding beam among the multi-beams B having passed through the openings 30 of the shaping aperture array substrate 203. Accordingly, the blanking aperture array substrate 204 can perform ON/OFF control of beams individually for each of the multi-beams B having passed through the shaping aperture array substrate 203. That is, the blanking aperture array substrate 204 can perform blanking control as to whether each of the multi-beams B is to be applied to the specimen W. The blanking aperture array substrate 204 is controlled by a deflection control circuit 130. The openings 40 of the blanking aperture array substrate 204 are larger than the openings 30 of the shaping aperture array substrate 203 and more easily pass each beam of the multi-beams B.

The blanking deflector 212 that performs collective blanking control of all the multi-beams is provided below the blanking aperture array substrate 204. The blanking deflector 212 can perform blanking control as to whether all the multi-beams B are to be applied to the specimen W.

The limiting aperture substrate 206 having an opening 50 formed in a central portion is provided below the blanking deflector 212. Electron beams deflected by the blanking aperture array substrate 204 or the blanking deflector 212 to be brought to a beam-OFF state are deviated from the position of the opening 50 at the center of the limiting aperture substrate 206 and are shielded by the limiting aperture substrate 206. This state in which the electron beams are shielded by the limiting aperture substrate 206 is referred to as “beam OFF”. Electron beams not having been deflected by the blanking aperture array substrate 204 and the blanking deflector 212 pass through the limiting aperture substrate 206 and are deflected by the deflectors 208 and 209 to be applied to desired positions on the specimen W. This state in which the electron beams pass through the opening 50 of the limiting aperture substrate 206 to be applied to the specimen W is referred to as “beam ON”.

As described above, the limiting aperture substrate 206 passes all the multi-beams B through the opening 50 provided at the center, or shields all the multi-beams B deflected by the blanking deflector 212.

The blanking deflector 212 is provided between the shaping aperture array substrate 203 or the blanking aperture array substrate 204 and the limiting aperture substrate 206. The blanking deflector 212 is controlled by the logic circuit 131 and the deflection control circuit 130 and performs blanking control as to whether the multi-beams B having passed through the blanking aperture array substrate 204 are to be applied as a whole to the specimen W. Accordingly, the whole multi-beams B can be controlled to be beam ON or beam OFF without changing the control state of the blanking aperture array substrate 204. The deflectors 208 and 209 are controlled by the deflection control circuit 130 via the DAC amplifier 134.

The limiting aperture driver 136 is connected to the limiting aperture substrate 206 and can move the limiting aperture substrate 206 in the X direction or the Y direction. The limiting aperture substrate 206 can move in an X-Y plane (a substantially horizontal plane) substantially perpendicular to the irradiation direction of the charged particle beam B0 or the multi-beams B.

The limiting aperture controller 135 is connected to the limiting aperture driver 136 and controls the limiting aperture driver 136. The limiting aperture controller 135 can control the location of the limiting aperture substrate 206 by controlling the limiting aperture driver 136.

For example, as described above, the multi-beams B are deflected by the blanking deflector 212 in a certain direction in the X-Y plane (the substantially horizontal plane) and is applied to a location deviated from the opening 50 of the limiting aperture substrate 206 in a beam-OFF (blanking) period. A direction in which the multi-beams B are deflected by the blanking deflector 212 is referred to as “deflection direction”. In this blanking period, the limiting aperture controller 135 moves the limiting aperture substrate 206 in the opposite direction to the deflection direction of the multi-beams B. Accordingly, scattered beams are less likely to pass through the opening 50 of the limiting aperture substrate 206 because of movement of the opening 50 of the limiting aperture substrate 206 in addition to the deflection of the whole multi-beams B caused by the blanking deflector 212.

The controller 160 can be formed of one or a plurality of computers, CPUs (Central Processing Units), PLCs (Programmable Logic Controllers), or the like. For example, the limiting aperture controller 135 can be formed of one or a plurality of computers, CPUs, or PLCs. The controller 160 may be formed integrally with the writing part 150 or may be formed as a separate unit. The limiting aperture driver 136 may be, for example, a piezoelectric element or an ultrasonic motor.

The stage controller 5 controls the operation of the stage 105 to move the stage 105 in the X direction or the Y direction (in a substantially horizontal direction).

The stage location meter 7 is formed of, for example, a laser length meter and irradiates the mirror 210 fixed on the stage 105 with laser light to measure the location of the stage 105 in the X direction on the basis of reflected light. Same components as the stage location meter 7 and the mirror 210 are provided also in the Y direction as well as in the X direction to also measure the location of the stage 105 in the Y direction.

FIG. 1 illustrates constituent elements necessary for explaining the first embodiment. The writing apparatus 100 may include other necessary constituent elements.

The writing apparatus 100 performs a writing operation by a raster scanning method in which shot beams are continuously and sequentially emitted while the XY stage 105 is moved. When a desired pattern is to be written, necessary beams according to the pattern are controlled to be beam ON or beam OFF by the blanking control.

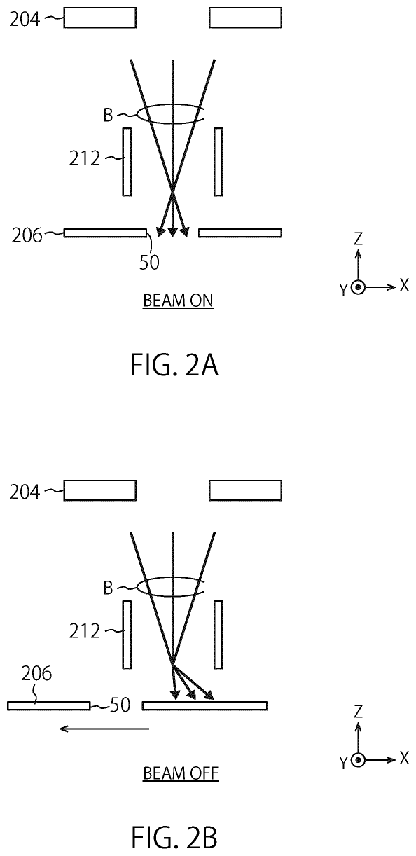

FIG. 2A is a conceptual diagram illustrating a state of the writing apparatus 100 in beam ON. FIG. 2B is a conceptual diagram illustrating a state of the writing apparatus 100 in beam OFF.

As illustrated in FIG. 2A, in beam ON, the multi-beams B from the blanking aperture array substrate 204 pass through the blanking deflector 212 and the opening 50 of the limiting aperture substrate 206 to be applied to the specimen W illustrated in FIG. 1. At that time, the blanking deflector 212 little deflects the multi-beams B and does not cause the multi-beams B to be shielded (blanked) by the limiting aperture substrate 206. The beam ON is, for example, a state used when writing processing is performed.

As illustrated in FIG. 2B, in beam OFF, the multi-beams B from the blanking aperture array substrate 204 are deflected in the +X direction by the blanking deflector 212. Furthermore, the limiting aperture controller 135 and the limiting aperture driver 136 move the limiting aperture substrate 206 in the opposite direction (the −X direction) to the deflection direction (the +X direction) from the arrangement location at the time of writing. By thus deflecting the multi-beams B in the +X direction and moving the limiting aperture substrate 206 in the −X direction, the limiting aperture substrate 206 can almost completely shield the multi-beams B. At that time, the limiting aperture substrate 206 can shield also scattered beams. That is, in the beam-OFF state according to the present embodiment, the multi-beams B and the scattered beams are shielded (blanked) by the limiting aperture substrate 206. The beam OFF is used, for example, in a preparatory period (for example, soaking processing or Z-map measurement) before writing in which the writing processing has not performed yet. In a case in which the specimen W is irradiated and scanned with the multi-beams B along a plurality of lines, the blanking period may be a period (stripe end) from the end of irradiation of a first line to the start of irradiation of the next second line.

A control method of the writing apparatus 100 according to the present embodiment is explained next.

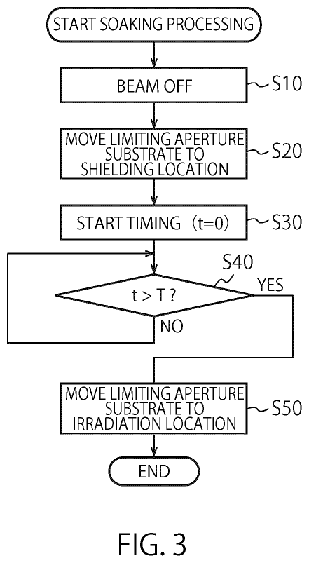

FIG. 3 is a flowchart illustrating a control method of the writing apparatus 100 in soaking processing. The soaking processing is pre-writing processing of waiting until the temperature of a specimen W such as a mask blank matches the temperature of the stage 105 in the writing chamber 103 after the specimen W is mounted on the stage 105. A soaking period is a period after the specimen W is mounted on the stage 105 before the specimen W has a predetermined temperature. In the soaking processing, the blanking aperture array substrate 204 and the blanking deflector 212 are in a beam-OFF state to prevent the specimen W from being irradiated with the multi-beams B. Therefore, the multi-beams B are shielded by the limiting aperture substrate 206 and do not reach the specimen W.

However, as described above, some of scattered beams scattered on the side surfaces of the openings 30 of the shaping aperture array substrate 203 and the like cannot be sufficiently shielded by the blanking aperture array substrate 204 and the blanking deflector 212 in some cases. There is a risk that some of these scattered beams pass through the blanking aperture array substrate 204 and the blanking deflector 212 to be applied to the specimen W. In such a case, the sensitive material on the specimen W is unintentionally locally exposed to the scattered beams.

In order to solve this problem, in the present embodiment, the limiting aperture controller 135 moves the limiting aperture substrate 206 in the opposite direction (for example, the −X direction) to the deflection direction (for example, the +X direction) of the multi-beams B in a period (blanking period) in which the blanking aperture array substrate 204 or the blanking deflector 212 is performing blanking control to prevent the specimen W from being irradiated with the multi-beams B. Accordingly, at the time of beam OFF, the multi-beams B can be greatly deviated from the opening 50 of the limiting aperture substrate 206 and the specimen W can be prevented from being exposed to the scattered beams.

For example, first, the blanking aperture array substrate 204 and/or the blanking deflector 212 deflect the whole multi-beams B to be applied onto the limiting aperture substrate 206 and cause the beams to be OFF (S10). At that time, for example, the whole multi-beams B are deflected in the +X direction.

Next or at the same time as Step S10, the limiting aperture controller 135 and the limiting aperture driver 136 move the limiting aperture substrate 206 in a plane substantially perpendicular to the axis direction (a Z direction) of the beams. For example, the limiting aperture substrate 206 is moved to a shielding location in the opposite direction to the deflection direction of the multi-beams B (S20). More specifically, the limiting aperture controller 135 and the limiting aperture driver 136 move the limiting aperture substrate 206 in the −X direction. This suppresses the multi-beams B leaked from the opening 50 of the limiting aperture substrate 206. At that time, it is preferable that the moving distance of the limiting aperture substrate 206 is equal to or more than the opening diameter of the opening 50. Accordingly, the opening 50 is greatly deviated from the opening 50 at the original location so as not to overlap therewith and the multi-beams B leaked from the opening 50 of the limiting aperture substrate 206 can be further suppressed.

Next or at the same time as Steps S10 and S20, a time t is reset to 0 (zero) and timing is started (S30). For example, the deflection control circuit 130 or the limiting aperture controller 135 includes a timer (not illustrated) and measures the time t from the start (t=0) of the soaking processing. A soaking processing time T is a time from when a specimen W is mounted on the stage 105 until when the temperature of the specimen W becomes a predetermined temperature substantially equal to the temperature of the stage 105 (a time to reach a state of equilibrium) and is set in advance. The soaking processing is continued until the time t reaches the soaking processing time T.

Next, the deflection control circuit 130 or the limiting aperture controller 135 compares the time t with the soaking processing time T (S40). When the time t has not reached the soaking processing time T (NO at S40), the deflection control circuit 130 or the limiting aperture controller 135 continues the timing (S40).

When the time t has reached the soaking processing time T (YES at S40), the limiting aperture controller 135 and the limiting aperture driver 136 returns the limiting aperture substrate 206 to the arrangement location at the time of writing where the multi-beams B are passed (S50). For example, the limiting aperture controller 135 and the limiting aperture driver 136 move the limiting aperture substrate 206 in the +X direction. This enables the multi-beams B to pass through the opening 50 of the limiting aperture substrate 206. At that time, the moving distance of the limiting aperture substrate 206 in the +X direction is the same as the moving distance at Step S20. Accordingly, the opening 50 is returned to the original arrangement location. The soaking processing then ends.

Subsequently, other pre-writing processing is performed, and the writing processing is started when the state is changed from beam OFF to beam ON.

According to the present embodiment, during the beam-OFF period of the soaking processing, the limiting aperture controller 135 moves, for example, the limiting aperture substrate 206 in the opposite direction to the deflection direction of the multi-beams B. Accordingly, the multi-beams B can be greatly deviated from the opening 50 of the limiting aperture substrate 206 and exposure of the specimen W to the scattered beams can be suppressed.

It is preferable that the moving direction of the limiting aperture substrate 206 in the blanking period is the opposite direction to the deflection direction of the multi-beams B in a plane (for example, a substantially horizontal plane) substantially perpendicular to the irradiation direction of the multi-beams B. Therefore, when the deflection direction of the multi-beams B is the +Y direction, it suffices that the moving direction of the limiting aperture substrate 206 is the −Y direction. When the deflection direction of the multi-beams B is an oblique direction to the X direction and the Y direction, it suffices that the moving direction of the limiting aperture substrate 206 is an oblique direction opposite to the deflection direction of the multi-beams B. However, the opposite direction does not need to have a phase difference of 180º and may have a phase difference of about 180º+10°. The same holds for the following embodiments.

### Second Embodiment

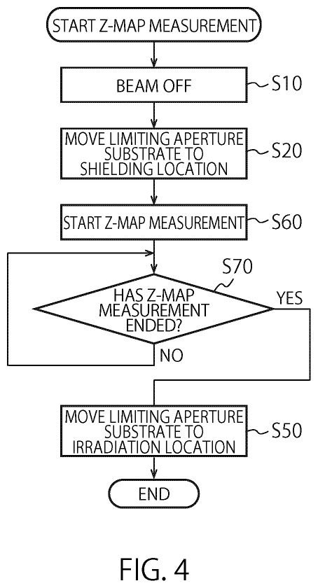

FIG. 4 is a flowchart illustrating a control method of the writing apparatus 100 in Z-map measurement processing. The Z-map measurement is processing of measuring the height (the location in the Z direction) of the surface of a specimen W and mapping the height to measure distortion of the specimen W. The Z-map measurement is performed by the deflection control circuit 130 after the soaking processing.

Also in the Z-map measurement, the blanking aperture array substrate 204 and the blanking deflector 212 are in a beam-OFF state to prevent the specimen W from being irradiated with the multi-beams B. Therefore, the multi-beams B are shielded by the limiting aperture substrate 206 and do not reach the specimen W.

First, processing at Steps S10 and S20 is performed. That is, the beams are caused to be OFF and the limiting aperture controller 135 and the limiting aperture driver 136 move the limiting aperture substrate 206 to a shielding location in the opposite direction to the deflection direction of the multi-beams B.

Next, the Z-map measurement is started (S60). In the Z-map measurement, it suffices to irradiate the surface of the specimen W with laser light and detect reflected light to detect the height (the location in the Z direction) of the surface of the specimen W. Illustrations and detailed explanations of a laser light generation device and a laser light detection device are omitted here.

The irradiation with the laser light is performed at substantially equal intervals in the surface of the specimen W. Therefore, the height location of the surface of the specimen W in the Z direction is measured two-dimensionally in a matrix. Data of a Z map is thereby obtained. The Z-map measurement is performed on the entire surface of the specimen W (NO at S70).

When the Z-map measurement has been performed on the entire surface of the specimen W and the Z map is complete, the Z-map measurement ends (YES at S70). The Z map is used in the writing processing to adjust the height of the specimen W or adjust the reducing lens 205 and/or the objective lens 207.

When the Z-map measurement ends (YES at S70), the limiting aperture controller 135 and the limiting aperture driver 136 return the limiting aperture substrate 206 to the irradiation location where the multi-beams B are passed (S50), similarly to Step S50 in FIG. 3. The Z-map measurement processing then ends.

Subsequently, other pre-writing processing is performed, and the writing processing is started when the state is changed from beam OFF to beam ON.

As described in the second embodiment, also in the Z-map measurement processing, the limiting aperture controller 135 moves the limiting aperture substrate 206 in the opposite direction to the deflection direction of the multi-beams B in the beam-OFF period. The configuration and other operations of the second embodiment may be identical to the configuration and the operations of the first embodiment. Accordingly, the second embodiment can attain identical effects as those of the first embodiment.

### Third Embodiment

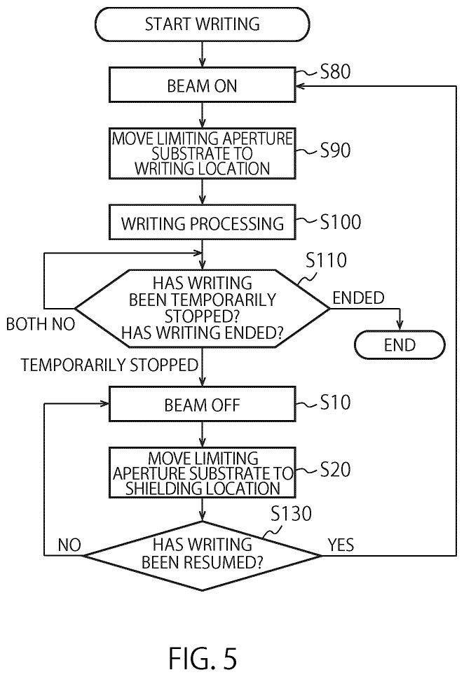

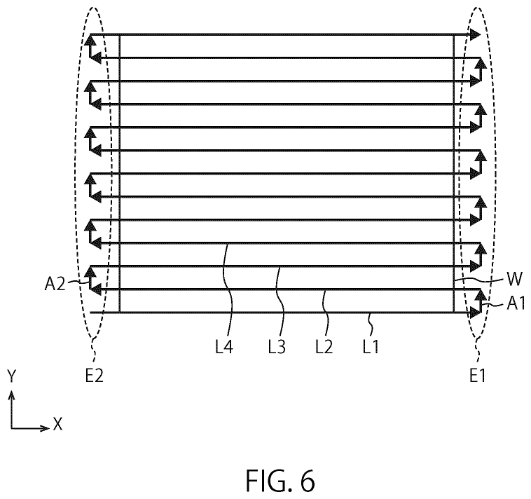

FIG. 5 is a flowchart illustrating a control method of the writing apparatus 100 in writing processing. FIG. 6 is a conceptual diagram illustrating scanning with the multi-beams B in the writing processing.

In the writing processing, to enable the sensitive material on the specimen W to be exposed in a desired pattern, the blanking aperture array substrate 204 and the blanking deflector 212 are in a beam-ON state. Accordingly, the surface of the specimen W is scanned with the multi-beams B and writing is performed.

The writing processing is performed after preprocessing such as the soaking processing and the Z-map measurement. As illustrated in FIG. 6, in the writing processing, the surface of the specimen W is scanned with the multi-beams B in a zigzag manner along a plurality of lines L1, L2, L3 . . . . The lines L1, L2, L3 . . . are also collectively referred to as “lines L”. At the time of the scanning with the multi-beams B along the lines L, the blanking aperture array substrate 204 and the blanking deflector 212 are in a beam-ON state.

In a period from the end of irradiation of a certain line (for example, L1) among the lines L to the start of irradiation of the next line (for example, L2), the multi-beams B move in an arrow-A1 direction at an end portion E1 of the specimen W. At that time, the writing processing is temporarily stopped and the blanking aperture substrate 204 and the blanking deflector 212 are in a beam-OFF state to prevent the specimen W from being irradiated with the multi-beams B. In a period from the end of irradiation of a certain line (for example, L2) to the start of irradiation of the next line (for example, L3), the multi-beams B move in an arrow-A2 direction at an end portion E2 of the specimen W. At that time, the writing processing is temporarily stopped and the blanking aperture array substrate 204 and the blanking deflector 212 are in a beam-OFF state to prevent the specimen W from being irradiated with the multi-beams B.

In this way, the writing processing is sometimes temporarily stopped between a certain line and the next line even in the middle of the writing processing. At that time, the writing apparatus 100 is in a beam-OFF state and the limiting aperture controller 135 and the limiting aperture driver 136 move the limiting aperture substrate 206 to a shielding location in the opposite direction to the deflection direction of the multi-beams B.

For example, when the writing processing is started, the limiting aperture controller 135 and the limiting aperture driver 136 are brought to beam ON to perform the writing processing (S80). At that time, the limiting aperture substrate 206 is arranged at a location (a writing location) where the multi-beams B are passed through the opening 50. This enables the multi-beams B to pass through the opening 50 and enables a desired pattern to be written on the specimen W.

Subsequently, the writing processing is performed (S100). At that time, scanning with the multi-beams B is performed along each of the lines L1, L2, L3 . . . on the surface of the specimen Was illustrated in FIG. 6 (NO at S110).

When the writing processing is temporarily stopped in the middle at the end portion E1 or E2 between a certain line and the next line (temporary stop at S110), the blanking aperture array substrate 204 and the blanking deflector 212 are brought to a beam-OFF state. (S10). At that time, as well as the beams caused to be OFF, the limiting aperture controller 135 and the limiting aperture driver 136 move the limiting aperture substrate 206 to a shielding location in the opposite direction to the deflection direction of the multi-beams B (S20).

The beam-OFF state is continued until the writing processing is resumed (NO at S130).

When the writing processing is resumed (YES at S130), the processing returns to Step S80 and is performed again from causing the beams to be ON.

When the scanning with the multi-beams B along all the lines L ends (END at S110), the writing processing ends.

As described above, in a stripe end period from the end of irradiation of a certain line to the start of irradiation of the next line in the writing processing, the limiting aperture controller 135 and the limiting aperture driver 136 are in a beam-OFF state. In this beam-OFF period, the limiting aperture controller 135 moves the limiting aperture substrate 206, for example, in the opposite direction to the deflection direction of the multi-beams B in a plane perpendicular to the irradiation axis direction of the multi-beams B.

The configuration and other operations of the third embodiment may be identical to the configuration and the operations of the first embodiment. Accordingly, the third embodiment can attain identical effects as those of the first embodiment. The third embodiment may be combined with the second embodiment. Further, the third embodiment may be applied to a state in which the writing with the multi-beams B is not performed, for example, to a case in which the writing is stopped due to error occurrence, Z-location measurement, and mark detection.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A writing apparatus that irradiates a predetermined position on an irradiation target with multiple charged particle beams to write a predetermined pattern on the irradiation target, the apparatus comprising:
a beam generation mechanism configured to generate multiple charged particle beams;
a blanking aperture mechanism comprising a limiting aperture substrate configured to shield the generated multiple charged particle beams and a deflector configured to deflect the multiple charged particle beams in a predetermined direction, and configured to blank the multiple charged particle beams;
a stage configured to have the irradiation target mounted thereon and to be movable;
a driver configured to move the limiting aperture substrate; and
a controller configured to control the writing apparatus, wherein
the controller moves the limiting aperture substrate from an arrangement location at a time of the writing in a plane perpendicular to an axial direction of the multiple charged particle beams in a period of the blanking, and returns the limiting aperture substrate to the arrangement location at a time of the writing.

2. The apparatus of claim 1, wherein the controller moves the limiting aperture substrate in an opposite direction to the predetermined direction.

3. The apparatus of claim 1, wherein a moving distance of the limiting aperture substrate is equal to or larger than an opening diameter of an aperture on the limiting aperture substrate.

4. The apparatus of claim 1, wherein the controller performs soaking for causing a temperature of the irradiation target to be constant in the blanking period.

5. The apparatus of claim 1, wherein the controller moves the limiting aperture substrate in an opposite direction to a deflection direction of the multiple charged particle beams in the blanking period.

6. The apparatus of claim 1, wherein the limiting aperture substrate moves in a substantially horizontal plane.

7. The apparatus of claim 1, wherein the blanking period is a preparatory period for the writing.

8. The apparatus of claim 1, wherein the blanking period is a period after the irradiation target is mounted on the stage and before the irradiation target has a predetermined temperature.

9. The apparatus of claim 1, wherein the blanking period is a period in which a height location of a surface of the irradiation target is measured.

10. The apparatus of claim 1, wherein the irradiation target is irradiated with the multiple charged particle beams along a plurality of lines at a time of irradiation of the irradiation target with the multiple charged particle beams, and the blanking period is a period from an end of irradiation of a first one of the lines to a start of irradiation of a next second line.

11. A writing method of irradiating a predetermined position on an irradiation target with multiple charged particle beams to write a predetermined pattern on the irradiation target, the method comprising:
generating multiple charged particle beams;
deflecting the generated multiple charged particle beams in a predetermined direction to blank the multiple charged particle beams with a limiting aperture substrate; and
moving the limiting aperture substrate from an arrangement location at a time of the writing in a plane perpendicular to an axial direction of the multiple charged particle beams in a period of the blanking, and returning the limiting aperture substrate to the arrangement location at a time of the writing.

12. The method of claim 11, wherein the controller moves the limiting aperture substrate in an opposite direction to the predetermined direction.

13. The method of claim 11, wherein a moving distance of the limiting aperture substrate is equal to or larger than an opening diameter of an aperture on the limiting aperture substrate.

14. The method of claim 11, wherein the controller performs soaking for causing a temperature of the irradiation target to be constant in the blanking period.

15. The method of claim 11, comprising moving the limiting aperture substrate in an opposite direction to a deflection direction of the multiple charged particle beams in the blanking period.

16. The method of claim 11, wherein the limiting aperture substrate moves in a substantially horizontal plane.

17. The method of claim 11, wherein the blanking period is a preparatory period for the writing.

18. The method of claim 11, wherein the blanking period is a period after the irradiation target is mounted on the stage and before the irradiation target has a predetermined temperature.

19. The method of claim 11, wherein the blanking period is a period in which a height location of a surface of the irradiation target is measured.

20. The method of claim 11, wherein the irradiation target is irradiated with the multiple charged particle beams along a plurality of lines at a time of irradiation of the irradiation target with the multiple charged particle beams, and the blanking period is a period from an end of irradiation of a first one of the lines to a start of irradiation of a next second line.
